(19) United States
(12) Patent Application Publication
(10) Pub. No.: US 2007/0171115 A1
(43) Pub. Date: Jul. 26, 2007

(54) GATE DRIVER, AND THIN FILM TRANSISTOR SUBSTRATE AND LIQUID CRYSTAL DISPLAY HAVING THE SAME

(75) Inventors: Beom Jun KIM, Seoul (KR); Shin Tack KANG, Yongin-Si (KR); Byeong Jae AHN, Suwon-Si (KR); Jong Hyuk LEE, Seoul (KR); Yu Jin KIM, Asan-Si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/620,393

(22) Filed: Jan. 5, 2007

(30) Foreign Application Priority Data
Jan. 10, 2006 (KR) 10-2006-0002843

(51) Int. Cl. H03M 1/12

(52) U.S. Cl. 341/155

(57) ABSTRACT

A gate driver for a liquid crystal display includes a shift register including a plurality of stages for outputting gate drive signals. Each of the stages includes a pull-up circuit for providing the gate drive signal to an output terminal in response to first and second clock signals, a pull-down circuit for providing a gate off signal to the output terminal, a pull-up driving circuit for driving the pull-up circuit in response to a first control signal, and a pull-down driving circuit for driving the pull-down circuit in response to a second control signal. Each of the stages includes a plurality of switching devices. A node of nodes where a signal line, through which the first clock signal, the second clock signal, the first control signal or the second control signal is applied, is electrically connected to a switching device includes at least two contacts.

### CROSS REFERENCE TO RELATED APPLICATION

This application claims priority to and the benefit of Korean Patent Application No. 10-2006-0002843, filed on Jan. 10, 2006, which is hereby incorporated by reference for all purposes as if fully set forth herein.

### BACKGROUND OF THE INVENTION

1. Field of the Invention

The present invention relates to a gate driver, and a thin film transistor substrate and a liquid crystal display having the same, and more particularly, to a gate driver structure that may be capable of preventing contact defects in a gate driver including amorphous silicon thin film transistors.

2. Discussion of the Background

Generally, unlike a conventional cathode ray tube (CRT), a liquid crystal display has the advantages of being thin and light weight, and it may have a large screen. Accordingly, liquid crystal displays have been actively developed, and they are frequently used as monitors for laptop and desktop computers, large-sized displays, and mobile terminal displays. Furthermore, the applicable fields of liquid crystal displays are rapidly expanding. In a liquid crystal display, the amount of transmitted light may be controlled according to an image signal applied to a plurality of control switches, which are arranged in a matrix, so that a desired image may be displayed.

A liquid crystal display may be classified as an amorphous silicon thin film transistor (TFT) liquid crystal display or a polysilicon TFT liquid crystal display. The amorphous silicon TFT has a mobility, which is one of a TFT's primary characteristics, that is about 100 to 200 times less than that of the polysilicon TFT, but large devices may be more easily manufactured with amorphous silicon TFTs. Additionally, the amorphous silicon TFT shows inferior electrical device characteristics but uniform ones, in comparison with that of polysilicon TFT's, and it may be sufficiently utilized as a pixel switching device. Thus, liquid crystal displays are often manufactured with amorphous silicon TFTs. On the other hand, the polysilicon TFT has mobility and device characteristics that are beyond the capability of the amorphous silicon TFT. In an amorphous silicon TFT liquid crystal display, only a pixel portion is formed in a liquid crystal panel and a driving circuit is then connected thereto using tape automated bonding (TAB) or chip on glass (COG). Conversely, with the polysilicon TFT liquid crystal display, an additional driving circuit is not required in forming a pixel portion since a data driving circuit and a gate driver may be simultaneously integrated. However, with the recent developments in amorphous silicon technology, a technique of embedding a gate driver with amorphous silicon TFTs in a liquid crystal panel has been developed.

FIG. 1 is a schematic diagram illustrating a configuration of a liquid crystal panel with a typical gate driver embedded therein. Referring to FIG. 1, the liquid crystal panel 100 includes a source driver 110 for driving data lines and a gate driver 120 for driving gate lines. The gate driver 120 includes a TFT as a switching device for connecting an external clock signal and the gate line, and a circuit for controlling the TFT. An amorphous silicon TFT may be used for the TFT and is embedded in a substrate, thereby reducing the number of external parts.

FIG. 2 is a schematic diagram illustrating a gate driver structure. Referring to FIG. 2, the gate driver includes a shift register having a plurality of stages SRC₁, SRC₂, SRC₃ and SRC₄ connected in cascade for sequentially activating gate lines G1, G2, G3 and G4 in response to a clock signal CKV and an inverted clock signal CKVB. When an initiation signal STV drives the first stage SRC₁, the first stage turns on the first gate line G1 in response to the clock signal CKV. The turned-on first gate line G1 drives the second stage SRC₂, which turns on the second gate line G2 in response to the inverted clock signal CKVB. The turned-on second gate line G2 drives the third stage SRC₃ and simultaneously turns off the first stage SRC₁. In this manner, the gate lines may be sequentially turned on.

If the reliability of a substrate with such a gate driver is evaluated under a condition of high temperature and humidity, e.g., for 500 to 1,000 hours at a temperature of 60° C. and a humidity of 95%, some of the contacts at circuit wiring nodes in the gate driver may become corroded, discolored and peeled off due to moisture penetration, thereby causing defective electrical connections at the nodes. Consequently, a gate drive signal may not be properly applied to the gate lines of the liquid crystal panel, resulting in display defect.

### SUMMARY OF THE INVENTION

The present invention provides a gate driver with a structure that may be capable of preventing contact defects due to discoloring and peeling of contacts caused by moisture penetration even when a substrate having the gate driver embedded is used under high temperature and humidity.

The present invention also provides a thin film transistor substrate and a liquid crystal display including the gate driver.

Additional features of the invention will be set forth in the description which follows, and in part will be apparent from the description, or may be learned by practice of the invention.

The present invention discloses a gate driver to drive a plurality of gate lines of a liquid crystal panel. The gate driver includes a shift register including a plurality of stages for outputting gate drive signals, and a stage includes a pull-up circuit for providing the gate drive signal to an output terminal in response to first and second clock signals, a pull-down circuit for providing a gate off signal to the output terminal, a pull-up driving circuit for driving the pull-up circuit in response to a first control signal, and a pull-down driving circuit for driving the pull-down circuit in response to a second control signal. The stage includes a plurality of switching devices, and at least one node of nodes where a signal line, through which the first clock signal, the second clock signal, the first control signal or the second control signal is applied, is electrically connected to a switching device includes at least two contacts.

The present invention also discloses a gate driver to drive a plurality of gate lines of a liquid crystal panel. The gate driver includes a shift register including a plurality of stages for outputting gate drive signals. A stage includes a pull-up circuit for providing the gate drive signal to an output terminal in response to first and second clock signals, a pull-down circuit for providing a gate off signal to the output terminal, a pull-up driving circuit for driving the pull-up circuit in response to a first control signal, and a pull-down driving circuit for driving the pull-down circuit in response to a second control signal. The stage includes a plurality of switching devices and a redundant switching device, which is connected to a switching device of the plurality of switching devices.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic diagram showing a configuration of a liquid crystal panel with a typical gate driver embedded therein.

FIG. 2 is a schematic diagram showing the structure of a gate driver.

FIG. 3A is a schematic circuit diagram of a conventional gate driver.

FIG. 3B is a graph showing measured values of currents at gate driver nodes.

FIG. 4 is a functional block diagram showing a shift register of a gate driver according to an exemplary embodiment of the present invention.

FIG. 5 is a schematic circuit diagram showing a gate driver according to an exemplary embodiment of the present invention.

FIG. 6 is a schematic cross-sectional view of contacts shown in FIG. 5.

FIG. 7 is a schematic circuit diagram showing a gate driver according to still another exemplary embodiment of the present invention.

FIG. 8 is a schematic cross-sectional view showing a liquid crystal display including a gate driver according to an exemplary embodiment of the present invention.

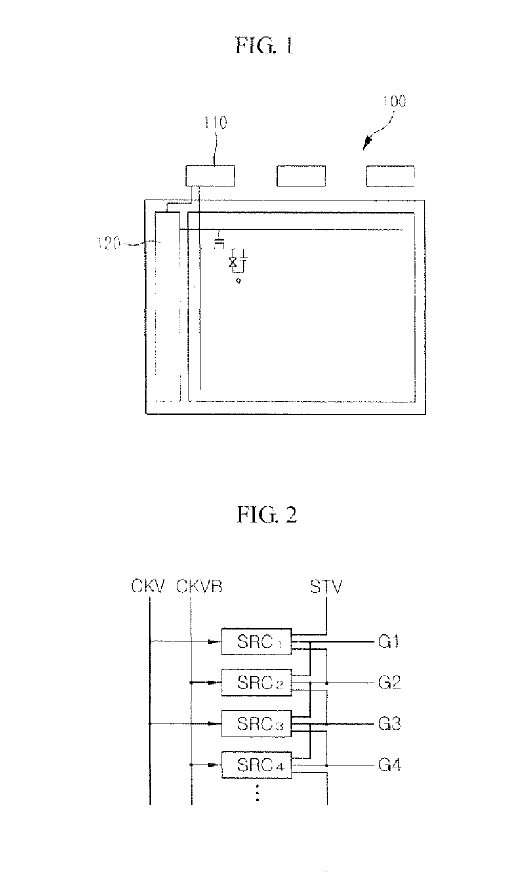

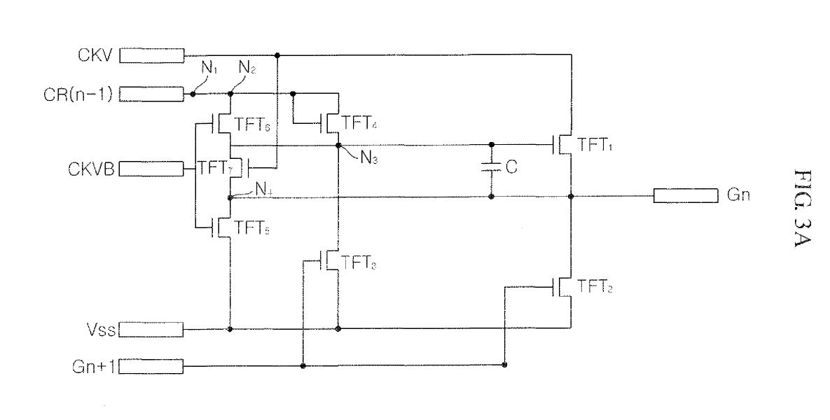

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region or substrate is referred to as being “on” another element, it can be directly on the other element or intervening elements may also be present. In contrast, when an element is referred to as being “directly on” another element, there are no intervening elements present.

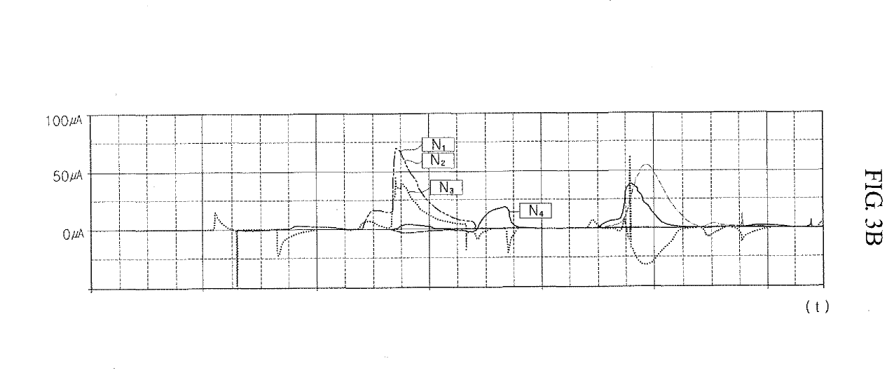

FIG. 3A is a schematic circuit diagram of a conventional gate driver, and FIG. 3B is a graph showing measured values of currents at gate driver nodes.

FIG. 3A shows one of a plurality of stages that are cascaded together to construct a shift register. The stage includes a plurality of amorphous silicon thin film transistors TFT₁ to TFT₇ and a capacitor C. Here, since signal input terminals, e.g., signal lines used to apply a clock signal CKV, an inverted clock signal CKVB, a previous stage carry signal CR₍ₙ₋₁₎ and the like, are formed in the same plane as the gate electrodes of the amorphous silicon TFTs, a plurality of contacts may be formed to electrically connect these signal lines to source/drain electrodes of the amorphous silicon TFTs.

In evaluating the reliability of a substrate with a gate driver, which includes the shift register having cascaded stages as shown in FIG. 3A, a current flowing through each node in the gate driver may be measured to determine why contact defects occur only in some contacts. Connection nodes between the signal lines and the amorphous silicon TFTs and connection nodes between the TFTs are shown in FIG. 3A. The electrical connections at each node may be made by contacts.

FIG. 3B is a graph showing measured values of current flowing through respective nodes. Referring to FIG. 3A and FIG. 3B, a current flowing through a first node N₁ and a second node N₂ is about 75 μA. This current is approximately twice that flowing through other nodes, e.g., the third and fourth nodes N₃ and N₄. At the second node N₂, a previous stage carry signal (CRₙ₋₁) input terminal is electrically connected to the amorphous silicon thin film transistor TFT₆.

The reliability evaluation performed on the substrate with the gate driver using amorphous silicon TFTs at high temperature and humidity showed that only contacts connected to nodes through which a high current flows, i.e., to the first node N₁ and the second node N₂, were corroded, discolored and peeled off, as described above. This is because a higher current flows through the contacts as compared with another nodes when the contacts are discolored due to moisture penetration, high heat is generated, and the contacts may peel off.

Accordingly, it is important to prevent electrical connections of the nodes from breaking even if contacts connected to the nodes through which higher currents flow are corroded, discolored and peeled off. Hence, according to exemplary embodiments of the present invention, a node may include at least two contacts, rather than a single contact, such that, even when one of the contacts is corroded, discolored and peeled off, another contact may maintain the electrical connection of the node. A gate driver with a structure that may be capable of preventing such contact defects will be described below in greater detail.

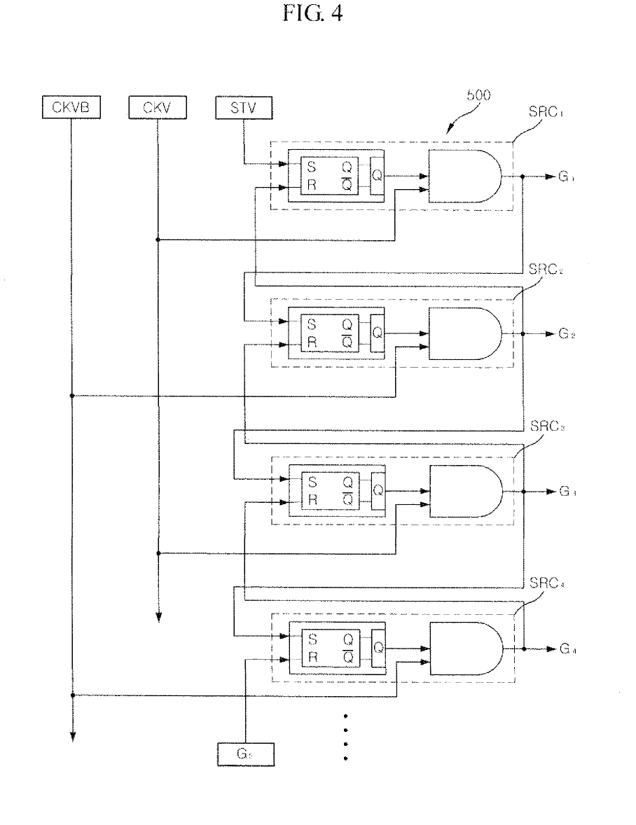

FIG. 4 is a functional block diagram showing a shift register of a gate driver according to an exemplary embodiment of the present invention.

Referring to FIG. 4, a gate driver 500 that outputs gate drive signals G₁, G₂, Gₙ includes a shift register, which includes a plurality of stages SRC₁, SRC₂, . . . , SRCₙ. Each stage SRC₁, SRC₂, . . . , SRCₙ includes a set-reset (S-R) latch and an AND gate. The S-R latch is set by a previous stage carry signal, i.e., a gate output signal, and is reset by a next stage carry signal, i.e., a gate output signal. The gate drive signal is outputted when the latch is set and a clock signal is high.

A first clock signal CKV is inputted to the odd stages SRC₁, SRC₃, . . . , and a second clock signal CKVB is inputted to the even stages SRC₂, SRC₄ . . . . The first clock signal CKV and the second clock signal CKVB have opposite phases. Except for the first and last stages SRC₁ and SRCₙ, an output terminal Gₙ of each stage is electrically connected to an input terminal of a next stage and an input terminal of a previous stage.

The first stage SRC₁ receives an initiation signal STV and outputs the first gate drive signal G₁ to select a first gate line. The first gate drive signal G₁ is inputted to an input terminal of the second stage SRC₂. The second stage SRC₂ receives the above signals together with the first gate drive signal G₁ from the previous stage and the third gate drive signal G₃, and outputs the second gate signal G₂ to select a second gate line. In this manner, the n-th stage SRCₙ outputs the n-th gate drive signal Gₙ through its output terminal. Here, amorphous silicon TFTs may be used for the aforementioned gate driver including the shift register with the plurality of stages connected in cascade, and the gate driver may be embedded at a side of a lower substrate, i.e., a TFT substrate, of a liquid crystal display.

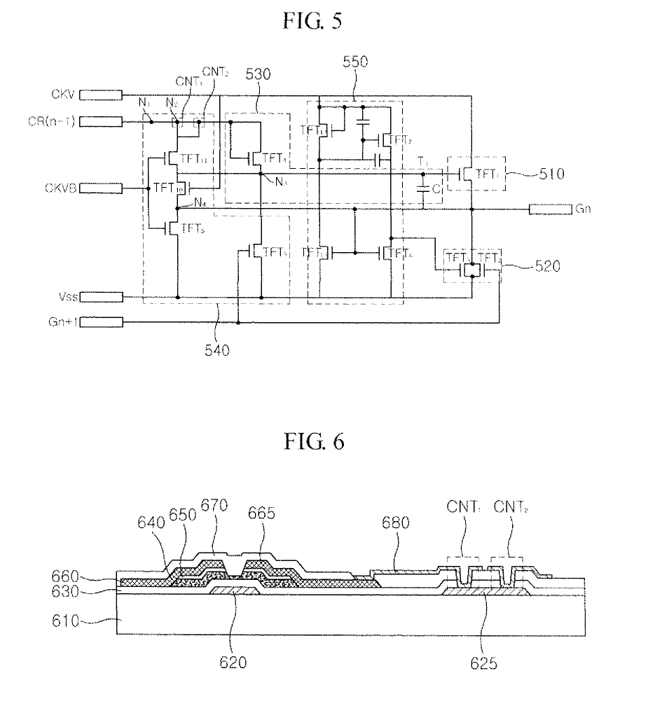

FIG. 5 is a schematic circuit diagram showing a gate driver according to an exemplary embodiment of the present invention.

Referring to FIG. 5, each stage in a shift register includes a pull-up circuit 510, a pull-down circuit 520, a pull-up driving circuit 530, a pull-down driving circuit 540, and an inverter 550.

The pull-up circuit 510 provides a clock signal CKV or an inverted clock signal CKVB, which has an opposite phase to that of the clock signal CKV, to an output terminal Gₙ. In this embodiment, the pull-up circuit 510 includes a TFT₁, which is electrically connected to a clock signal (CKV) input terminal to output a gate drive signal.

The pull-up driving circuit 530, which drives the pull-up circuit 510, includes a TFT₄ and a capacitor C. The capacitor C is coupled between a node T₁ and the output terminal Gₙ, and TFT₄ is coupled with a control signal input terminal CR₍ₙ₋₁₎ for receiving a carry signal, i.e., a gate drive signal, from a previous stage. When a high signal is input to the control signal input terminal CR₍ₙ₋₁₎, charges accumulate in the capacitor C and TFT₁ turns on. Accordingly, the clock signal CKV is output to the output terminal Gₙ to turn on the amorphous silicon TFTs on the gate line.

The pull-down circuit 520 outputs a gate off signal to the output terminal Gₙ, and it is driven by the pull-down driving circuit 540.

The pull-down circuit 520 includes TFT₂ and TFT₃. TFT₂ is coupled with a gate off signal input terminal Vss to which the gate off signal is input. When TFT₂ receives a next stage gate drive signal Gₙ₊₁, it discharges the gate drive signal as the gate off signal. TFT₃ keeps the level of the gate off signal in synchronization with the clock signal CKV.

The pull-down driving circuit 540 drives the pull-down circuit 520 and includes four TFTs TFT₅, TFT₉, TFT₁₀, and TFT₁₁. TFT₅ keeps the level of the gate off signal in synchronization with the inverted clock signal CKVB, and TFT₉ discharges the gate drive signal as the gate off signal. TFT₁₀ and TFT₁₁ keep the node T₁ at an off level in response to the clock signal CKV and the inverted clock signal CKVB, respectively. The inverter 550 includes four TFTs TFT₇, TFT₈, TFT₁₂, and TFT₁₃ for driving TFT₃. As described above, in this embodiment, the second node N₂, through which a higher current flows than that which flows through other nodes such as nodes N₃ and N₄, includes two contacts CNT₁ and CNT₂. While shown as having two contacts CNT₁ and CNT₂, the second node N₂ may include more than two contacts.

Although the second node N₂, (i.e. the node between the control signal input terminal CR₍ₙ₋₁₎, which receives the previous stage gate drive signal, and TFT₁₁), has been described as including two contacts in this embodiment, two or more contacts may also be formed at other nodes. A transparent conductor such as ITO may be used for the contacts.

As described above, two or more contacts may be formed at a node through which a higher current flows. Thus, even if one contact becomes discolored and peels off due to moisture penetration, the node connection may still be made by other contacts so that the gate drive signal may be output normally.

FIG. 6 is a schematic sectional view of contacts shown in FIG. 5. Referring to FIG. 6, two contacts CNT₁ and CNT₂ are arranged at the node between the control signal input terminal CR₍ₙ₋₁₎ and the TFT₁₁.

A first conductive film may be formed on a substrate 610. A gate electrode 620 and a signal line 625, which is coupled with a control signal input terminal CR₍ₙ₋₁₎, may then be formed through a patterning process using a photosensitive film mask.

A gate insulating film 630, an active layer 640, and an ohmic contact layer 650 may be sequentially formed, and an active region of a TFT may be formed through an etching process using a photosensitive film mask pattern. Here, an amorphous silicon layer, which is made of the same material as the active layer of the TFT on a liquid crystal panel, may be used for the active layer 640. The ohmic contact layer 650 may be a silicide layer or an amorphous silicon layer doped with N-type or P-type dopants.

A second conductive film may then be formed on an entire surface of the substrate and etched using a photosensitive film mask pattern to form source and drain electrodes 660 and 665 and a source line.

An insulating film 670 may be formed on the source and drain electrodes and the source line. A portion of the insulating film on the drain electrode 665 may be partially removed to form a contact hole, and portions of the gate insulating film 630 and the insulating film 670 on the signal line 625, which is coupled with the control signal input terminal CR₍ₙ₋₁₎, may be partially removed to form two contact holes. A conductive layer 680 may be formed thereon to form dual contacts CNT₁ and CNT₂. Here, a transparent conductor, e.g., ITO or IZO, may be used for the conductive layer 680.

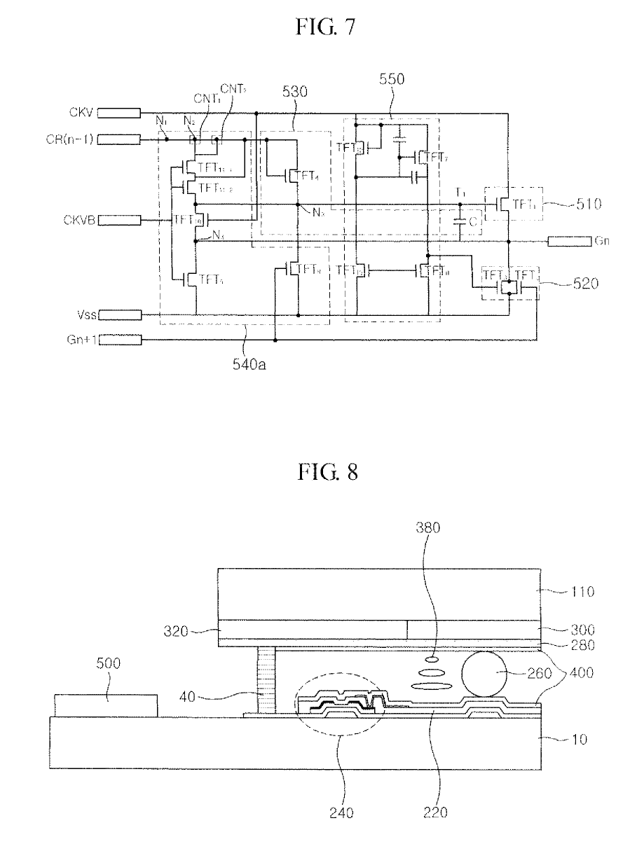

FIG. 7 is a schematic circuit diagram for each stage that may be used in a shift register according to still another exemplary embodiment of the present invention. This shift register differs from that shown in the embodiment of FIG. 5 in that an additional, redundant TFT is coupled with a predetermined TFT. Since the shift registers of the two embodiments have similar structures for preventing contact defects by forming a plurality of contacts at a certain node, only different portions will be described below.

Referring to FIG. 7, each stage in the shift register includes a pull-up circuit 510, a pull-down circuit 520, a pull-up driving circuit 530, a pull-down driving circuit 540a, and an inverter 550.

The pull-down driving circuit 540a drives the pull-down circuit 520 and includes four TFTs TFT₅, TFT₉, TFT₁₀, and TFT₁₁₋₁ and one redundant TFT TFT₁₁₋₂. TFT₅ keeps the level of a gate off signal in synchronization with an inverted clock signal CKVB, TFT₉ discharges the gate drive signal as a gate off signal, and TFT₁₀ and TFT₁₁₋₁ keep a node T₁ at an off level in response to the clock signal CKV and the inverted clock signal CKVB, respectively. Further, the redundant TFT TFT₁₁₋₂ is coupled with TFT₁₁₋₁ in the event that TFT₁₁₋₁ is defective. Consequently, when any one of the TFTs does not operate due to a defective contact, the other TFT may operate.

As described above, the second node N₂ of the first and second nodes N₁ and N₂, through which a current higher than that on the other nodes flows, includes the two contacts CNT₁ and CNT₂ in this embodiment. However, the second node N₂ may include more than two contacts.

FIG. 8 is a schematic sectional view showing a liquid crystal display including a gate driver according to an exemplary embodiment of the present invention.

Referring to FIG. 8, a black matrix 320, a color filter 300 and a common electrode 280 may be sequentially formed on a color filter substrate 110 of the liquid crystal display.

The black matrix 320 may be formed between a color filter and a pixel to shield light leakage. The color filter 300 may be formed of a resin film including dyes or pigments of three basic colors (red, green and blue). The common electrode 280 may be formed of a transparent conductor such as, e.g. ITO, or the like, and it applies a voltage to a liquid crystal cell.

A TFT 240, which is a switching device for applying or blocking a signal voltage to a liquid crystal, an ITO pixel electrode 220, which applies the signal voltage applied to the TFT to the liquid crystal cell, and a storage capacitor (not shown), which sustains the signal voltage applied to the pixel electrode for at least a predetermined period of time, are formed on a TFT substrate 10. A thin organic film made of polyimide, i.e., an orientation film 400 that orients the liquid crystal, is formed on top surfaces of the color filter substrate 110 and the TFT substrate 10. A spacer 260, which secures a space between the color filter substrate 110 and the TFT substrate 10, is disposed between the color filter substrate and the TFT substrate. A liquid crystal layer 380 is inserted into the space defined by the spacer 260. A shielding pattern 40 is formed at peripheral portions of the substrates so that the color filter substrate 110 may be bonded with the TFT substrate 10. Meanwhile, the shielding pattern 40 may be formed nearly in peripheral circuits.

A gate driver 500, which outputs a gate drive signal to turn on/off the TFT 240, may be embedded in a side on the top surface of the TFT substrate 10. Since TFTs used as switching devices in the gate driver 500 are also amorphous silicon TFTs, like TFT 240 included in the pixel, they may be fabricated through the same fabrication process, thereby significantly simplifying the fabrication process as compared with the case of using polysilicon TFTs. Further, as described above, a gate-driver node, through which a high current flows, may include at least two contacts instead of just one. Thus, even if a contact peels off, the gate drive signal may still be outputted normally.

A driving principle of such a liquid crystal display will be described below. When each gate line for one frame is selected by the gate driver 500 and a gate drive signal is applied to the selected gate line, the gate drive signal is applied to the gate electrode of the TFT 240, thereby opening a channel of the TFT. At this time, a source driver (not shown) delivers an image signal voltage depending on image information to the data line. The signal voltage delivered to the data line is charged in the liquid crystal capacitor and the storage capacitor through the opened TFT channel. When the TFT channel closes, the voltage charged in the liquid crystal capacitor and the storage capacitor is sustained, and the charged voltage is sustained in the pixel until the next frame by means of the storage capacitor provided for voltage charge.

As described above, according to exemplary embodiments of the present invention, two or more contacts may be included at a certain node. Thus, even if a contact becomes corroded, discolored and peeled off, the connection to the node may be made by another contact, thereby preventing contact defect.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A gate driver to drive a plurality of gate lines of a liquid crystal panel, comprising:
a shift register comprising a plurality of stages to output gate drive signals,
wherein a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal,
the stage comprises a plurality of switching devices, and
at least one node of nodes where a signal line, through which the first clock signal, the second clock signal, the first control signal or the second control signal is applied, is electrically connected to a switching device includes at least two contacts.

2. The gate driver of claim 1, wherein the switching device is a thin film transistor comprising an amorphous silicon active layer.

3. The gate driver of claim 1, wherein the at least one node is a node where the signal line, through which the first control signal is applied, is electrically connected to the switching device.

4. The gate driver of claim 3, wherein the first control signal is a gate drive signal of a previous stage.

5. The gate driver of claim 1, wherein the at least two contacts comprise a transparent conductor.

6. The gate driver of claim 5, wherein the transparent conductor comprises indium tin oxide (ITO).

7. The gate driver of claim 1, wherein the at least two contacts are formed in the different location.

8. The gate driver of claim 1, the current of the node including the at least two contacts is the largest in the nodes.

9. The gate driver of claim 1, the current of the node including the at least two contacts is about 75 μA.

10. A gate driver to drive a plurality of gate lines of a liquid crystal panel, comprising:
a shift register comprising a plurality of stages to output gate drive signals,
wherein a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal, and
the stage comprises a plurality of switching devices and a redundant switching device, the redundant switching device being connected to a first switching device of the plurality of switching devices.

11. The gate driver of claim 10, wherein the redundant switching device is connected to at least one switching device included in the pull-down driving circuit.

12. The gate driver of claim 10, wherein a first node of nodes where a signal line, through which the first clock signal, the second clock signal, the first control signal or the second control signal is applied, is electrically connected to a switching device includes at least two contacts.

13. The gate driver of claim 10, wherein the switching devices comprise a thin film transistor comprising an amorphous silicon active layer.

14. The gate driver of claim 12, wherein the first node is a node where the signal line, through which the first control signal is applied, is electrically connected to the switching device.

15. The gate driver of claim 14, wherein the first control signal is a gate drive signal of a previous stage.

16. The gate driver of claim 12, wherein the at least two contacts comprise a transparent conductor.

17. The gate driver of claim 16, wherein the transparent conductor comprises indium tin oxide (ITO).

18. A thin film transistor substrate, comprising:
a substrate comprising pixels arranged in a matrix, each of the pixels comprising a switching thin film transistor, a pixel electrode coupled with the switching thin film transistor, and a storage capacitor coupled with the pixel electrode; and
a gate driver arranged on the substrate to drive a plurality of gate lines arranged on the substrate,
wherein the gate driver comprises a shift register comprising a plurality of stages to output gate drive signals,
a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal,
the stage comprises a plurality of switching devices, and
at least one node of nodes where a signal line, through which the first clock signal, the second clock signal, the first control signal or the second control signal is applied, is electrically connected to a switching device includes at least two contacts.

19. The substrate of claim 18, wherein the at least one node is a node where the signal line, through which the first control signal is applied, is electrically connected to the switching device.

20. The substrate of claim 19, wherein the first control signal is a gate drive signal of a previous stage.

21. The substrate of claim 18, wherein the switching thin film transistor is an amorphous silicon thin film transistor.

22. A thin film transistor substrate, comprising:
a substrate comprising pixels arranged in a matrix, each of the pixels comprising a switching thin film transistor, a pixel electrode coupled with the switching thin film transistor, and a storage capacitor coupled with the pixel electrode; and
a gate driver arranged on the substrate to drive a plurality of gate lines arranged on the substrate,
wherein the gate driver comprises a shift register comprising a plurality of stages to output gate drive signals,
a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal, and
the stage comprises a plurality of switching devices and a redundant switching device, the redundant switching device being connected to a first switching device of the plurality of switching devices.

23. The substrate of claim 22, wherein the redundant switching device is connected to at least one switching device included in the pull-down driving circuit.

24. The substrate of claim 22, wherein a first node of nodes where a signal line, through which the first clock signal, the second clock signal, the first control signal or the second control signal is applied, is electrically connected to a switching device includes at least two contacts.

25. The substrate of claim 24, wherein the first node is a node where the signal line, through which the first control signal is applied, is electrically connected to the switching device.

26. The substrate of claim 25, wherein the first control signal is a gate drive signal of a previous stage.

27. The substrate of claim 22, wherein the switching thin film transistor is an amorphous silicon thin film transistor.

28. A liquid crystal display, comprising:
a thin film transistor substrate comprising a gate driver and a plurality of pixels, each of the pixels comprising a switching thin film transistor, a pixel electrode coupled with the switching thin film transistor, and a storage capacitor coupled with the pixel electrode; and
a color filter substrate comprising a color filter and a common electrode, the common electrode to apply a voltage to the liquid crystal,
wherein the gate driver comprises a shift register comprising a plurality of stages to output gate drive signals,
a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal,
the stage comprises a plurality of switching devices, and
at least one node of nodes where a signal line, through which the first clock signal, the second clock signal, the first control signal or the second control signal is applied, is electrically connected to a switching device includes at least two contacts.

29. A liquid crystal display, comprising:
a thin film transistor substrate comprising a gate driver and a plurality of pixels, each of the pixels comprising a switching thin film transistor, a pixel electrode coupled with the switching thin film transistor, and a storage capacitor coupled with the pixel electrode; and
a color filter substrate comprising a color filter and a common electrode, the common electrode to apply a voltage to the liquid crystal,
wherein the gate driver comprises a shift register comprising a plurality of stages to output gate drive signals,
a stage comprises a pull-up circuit to provide the gate drive signal to an output terminal in response to a first clock signal and a second clock signal, a pull-down circuit to provide a gate off signal to the output terminal, a pull-up driving circuit to drive the pull-up circuit in response to a first control signal, and a pull-down driving circuit to drive the pull-down circuit in response to a second control signal, and
the stage comprises a plurality of switching devices and a redundant switching device, the redundant switching device being connected to a switching device of the plurality of switching devices.
